(19) United States
(12) Patent Application Publication
(10) Pub. No.: US 2008/0157149 A1
(43) Pub. Date: Jul. 3, 2008

(54) CMOS image sensor and method for manufacturing the same

(75) Inventor: Seung Hyun Kim, Pocheon-goon (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/001,649

(22) Filed: Dec. 11, 2007

(30) Foreign Application Priority Data
Dec. 27, 2006 (KR) 10-2006-0134531

(51) Int. Cl. H01L 27/146; H01L 21/04

(52) U.S. Cl. 257/292; 438/73; 257/E21.04; 257/E27.133

(57) ABSTRACT

A CMOS image sensor may include a gate electrode on a gate insulating layer in an active region of a semiconductor substrate; a photodiode region in the semiconductor substrate on one side of the gate electrode; a floating diffusion region in the semiconductor substrate on another side of the gate electrode; and a complementary impurity region in the semiconductor substrate on the other side of the gate electrode, overlapping with the floating diffusion region.

The present application claims priority under 35 U.S.C. 119 and 35 U.S.C. 365 to Korean Patent Application No. 10-2006-0134531 (filed on Dec. 27, 2006), which is hereby incorporated by reference in its entirety.

### BACKGROUND

### Description of the Related Art

Generally, an image sensor, which is a semiconductor device converting optical images into electrical signals, may be largely classified into a charge coupled device (CCD) and a complementary metal oxide silicon (CMOS) image sensor.

The charge coupled device (CCD) contains a plurality of vertical charge coupled devices (VCCD) formed between the respective vertical photodiodes arranged in a matrix form to vertically transfer the charges generated from the respective photodiodes, the plurality of photodiodes converting light signals into electrical signals being arranged in a matrix form, a horizontal charge coupled device (HCCD) transferring the charges transferred by means of the respective vertical charge coupled devices, and a sense amplifier sensing the horizontally transferred charges to output them in electrical signals.

However, such a CCD has disadvantages of a relatively complicated driving manner, a relatively large power consumption, and a relatively complicated manufacturing process since multi-stage photolithography processes are used.

Also, it is difficult for the CCD to integrate a control circuit, a signal processing circuit, an A/D converter, etc., on a CCD chip, so that the CCD has a disadvantage of difficulty in miniaturizing a product.

Recently, as a next generation image sensor for overcoming the disadvantages of the CCD, a CMOS image sensor has been spotlighted.

The CMOS image sensor is a device adopting a switching manner to sequentially detect the outputs of the respective unit pixels by means of MOS transistors. The MOS transistors generally correspond to the number of unit pixels, and the CMOS image sensor may be made using a CMOS technique enabling inclusion of a control circuit and a signal processing circuit, etc., as peripheral circuits on the semiconductor substrate.

In other words, the CMOS image sensor forms the photodiode and the MOS transistors in the unit pixels to sequentially detect the electrical signals of the respective unit pixels, implementing an image.

The CMOS image sensor uses CMOS manufacturing techniques so that it has advantages of a small power consumption and a simple manufacturing process (e.g., relatively few photolithography processing steps).

Also, the CMOS image sensor can integrate a control circuit, a signal processing circuit, and an A/D converter, etc., on a CMOS image sensor chip so that it has an advantage of easiness in miniaturizing a product and/or integrating greater functionality onto a single chip.

Therefore, at the present, the CMOS image sensor has been widely used in various applications and products such as digital still cameras, and digital video cameras, etc.

Meanwhile, the CMOS image sensor can be classified into a 3T type, a 4T type, and a 5T type, etc., depending on the number of transistors per unit pixel. The 3T type CMOS image sensor is comprised of a photodiode and three transistors per unit pixel, while the 4T type CMOS image sensor is comprised of a photodiode and four transistors per unit pixel.

### SUMMARY OF THE INVENTION

Embodiments of the invention relate to a CMOS image sensor and a method for manufacturing the same, adapted to make a reset of a photodiode easy as well as to allow the electrons generated from the photodiode to be easily transferred into a floating diffusion region by making the width of a transfer transistor large and/or the area of a floating diffusion region small, thereby improving the characteristics of the image sensor.

A CMOS image sensor according to one embodiment comprises a gate electrode on a gate insulating layer in an active region of a semiconductor substrate having a predetermined interval; a photodiode region in the semiconductor substrate on one side of the gate electrode; a floating diffusion region in the semiconductor substrate on another side of the gate electrode; and a complementary impurity region in the semiconductor substrate overlapping the floating diffusion region.

### BRIEF DESCRIPTION OF THE DRAWINGS

FIG. 1 is a layout showing a unit pixel of a CMOS image sensor having a structure comprised of 4Tr and 1PD according to the embodiment;

FIG. 2 is a cross-sectional view showing a CMOS image sensor according to the embodiment taken along lines II-II′ of FIG. 1; and

FIGS. 3 to 5 are process cross-sectional views showing a method for manufacturing a CMOS image sensor according to the embodiment.

### DETAILED DESCRIPTION OF THE EMBODIMENTS

Hereinafter, a CMOS image sensor and a method for manufacturing the same according to embodiments of the invention will be described in detail with reference to the accompanying drawings.

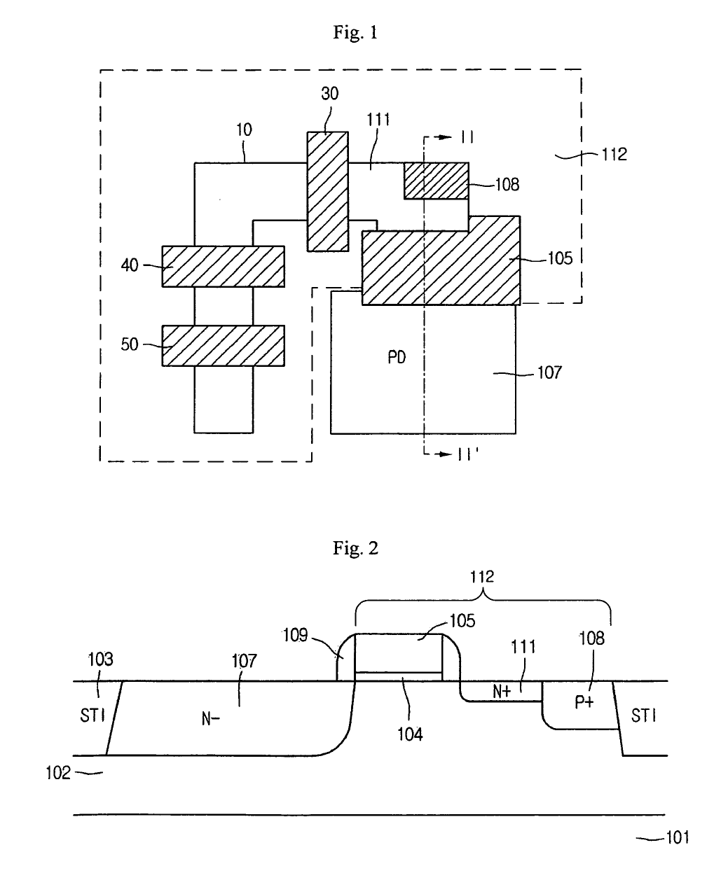

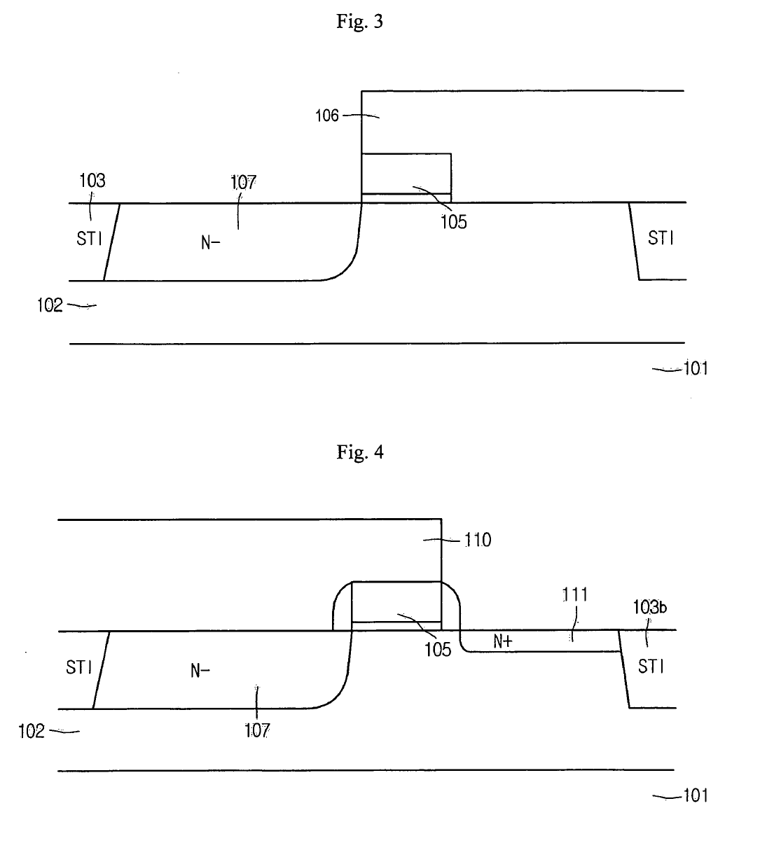

FIG. 1 is a layout view showing a unit pixel of a CMOS image sensor having a structure comprised of 4 transistors and 1 photodiode (PD) according to an embodiment, and FIG. 2 is a cross-sectional view showing the CMOS image sensor of FIG. 1 taken along lines II-II′ of FIG. 1.

FIGS. 1 and 2 show a unit pixel comprising a photodiode PD and four MOS transistors, formed on an epi layer 102 on the surface of a semiconductor substrate 101 (e.g., single-crystal silicon wafer). The substrate has an active region and a device isolating region (e.g., STI); a device isolating layer 103 formed in the device isolating region of the semiconductor substrate 101 provided with the epi layer 102; a gate electrode 105 formed on a gate insulating layer 104 in the active region of the semiconductor substrate 101 having a predetermined interval; a photodiode region 107 formed in the semiconductor substrate 101 on one side of the gate electrode 105; a floating diffusion region 111 formed in a transistor region 112 of the semiconductor substrate 101 adjacent to the opposite side of gate electrode 105; a complementary impurity region 108 overlapping floating diffusion region 111; and an insulating layer sidewall 109 formed on sides of the gate electrode 105.

Herein, the gate electrode 105 is the gate electrode of a transfer transistor for transferring the photocharges collected in the photodiode region 107 to the floating diffusion region 111. As shown in FIG. 1, one side of the gate electrode 105 is aligned with an end of the photodiode region 107.

And, as shown in FIG. 2, at least a portion of the complementary impurity region 108 is in, contacting or adjacent to the floating diffusion region 111, and at least a portion of the floating diffusion region 111 is between the complementary impurity region 108 and the gate electrode 105.

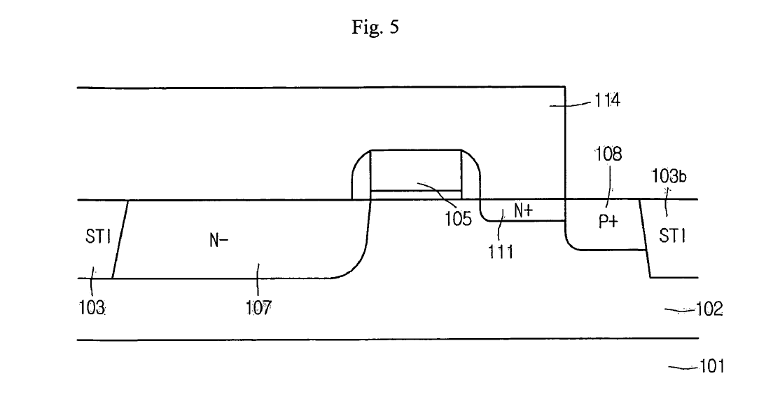

FIGS. 3 to 5 are process cross-sectional views showing a method for manufacturing a CMOS image sensor according to various embodiments.

As shown in FIG. 3, an epi layer 102 can be formed on the semiconductor substrate 101 by epitaxial growth on the semiconductor substrate 101. When the substrate 101 comprises single-crystal silicon, the epi layer 102 generally comprises silicon or silicon-germanium. A device isolating layer 103 is formed in the epi layer 102 for isolating devices.

Herein, the epi layer largely and deeply forms a depletion region in a photodiode region to be formed later and this is to increase the capability of a low voltage photodiode for collecting photogenerated electrons and further to improve photosensitivity. The semiconductor substrate 101 can, for example, comprise a P type epi layer on an N type substrate.

Herein, although not shown in the drawings, a method for forming the device isolating layer 103 will be described as follows. First, a pad oxide film, a pad nitride film, and a tetraethyl orthosilicate (TEOS) oxide film are sequentially formed on the semiconductor substrate, and a photoresist layer is formed on the TEOS oxide film. A photoresist layer is exposed and developed using a mask defining an active region and a device isolating region and then is patterned. At this time, the photoresist layer over the device isolating region is removed. Then, the pad oxide film, the pad nitride film, and the TEOS oxide film of the device isolating region are selectively removed using the patterned photoresist layer as a mask.

Next, the semiconductor substrate in the device isolating region is etched to a predetermined depth using the patterned pad oxide film, pad nitride film, and TEOS oxide film as a mask to form a trench. Then, the photoresist layer is completely removed.

Then, a sacrificial oxide film is thinly formed in the trench, and an O3 TEOS layer is formed on the substrate to fill the trench. At this time, the sacrificial oxide is formed in the inner wall of the trench and the O3 TEOS layer is performed at a temperature of about 1000° C. or more.

The excess O3 TEOS layer is removed by chemical mechanical polishing (CMP) so that only the trench region is filled with insulator material, forming a device isolating layer 103 inside the trench. Thereafter, the pad oxide film, the pad nitride film, and the TEOS oxide film are removed.

A gate insulating layer 104 and a conductive layer (for example, a polycrystalline silicon layer containing a high concentration of dopant) are sequentially deposited over the semiconductor substrate 101 provided with the device isolating layer 103. Herein, the gate insulating layer 104 may be formed using a thermal oxidation process or a CVD method. The gate electrode 105 of each transistor is formed by selectively removing (e.g., patterning) the conductive layer and the gate insulating layer 104.

As shown in FIG. 3, a first photoresist 106 is applied over the semiconductor substrate 101 provided with the gate electrode 105, and the first photoresist 106 is selectively patterned by an exposure process and a development process. Herein, the patterned first photoresist 106 exposes the surface of the semiconductor substrate 101 on one side of the gate electrode 105. A low-concentration N type impurity ion is implanted in the exposed region of the semiconductor substrate 101 using the patterned first photoresist 106 as a mask to form a photodiode region 107 in the active region of the semiconductor substrate 101 on the one side of the gate electrode 105.

As shown in FIG. 4, the first photoresist pattern 106 is completely removed and an insulating layer is formed over the semiconductor substrate 101. Herein, the insulating layer may be formed by stacking a nitride film and a TEOS oxide film, or may be formed in a single layer. Thereafter, an insulating layer sidewall 109 is formed on sides of the gate electrode 105 by anisotropic etching (e.g., reactive ion etching, or RIE]) the insulating layer.

A second photoresist 110 is applied over the semiconductor substrate 101 provided with the insulating layer sidewalls 109, and is patterned by an exposure process and a development process to expose a source/drain region of each transistor in the transistor region 112 (see FIGS. 1-2). A high-concentration N+ type impurity ion is implanted into the exposed source/drain region using the patterned second photoresist 110, the transistor gates (e.g., 105, 30 40 and 50) and insulating sidewalls 109 as a mask to form source/drain impurity regions including floating diffusion region 111.

At this time, a floating diffusion region 111, which is generally the source/drain impurity region of a transfer transistor opposite to the photodiode, is formed in the active region on the other (opposite) side of the gate electrode 105. Herein, the floating diffusion region 111 may be formed in the entire region between gate 105 and STI layer 103b.

As shown in FIG. 5, the second photoresist pattern 110 is removed, and a third photoresist pattern 114 is formed, exposing part of the floating diffusion region 111 (and optionally part or all of STI layer 103b). A high concentration of p-type impurity ions are implanted into the exposed part of the floating diffusion region 111 using the patterned third photoresist 114 as a mask to form complementary impurity region 108. Preferably, the concentration of p-type impurity ions in the complementary impurity region 108 is at least equal to the concentration of n-type impurity ions in the floating diffusion region 111. The size and/or shape of the complementary impurity region 108 is not critical, as long as the complementary impurity region 108 overlaps the floating diffusion region 111, but in various embodiments, the complementary impurity region 108 overlaps at least 10%, 20% or 25% of the floating diffusion region 111, up to 35%, 50% or 70% of the floating diffusion region 111. Such a structure effectively reduces the size of the floating diffusion region 111, increasing its sensitivity to the amount of charge carriers generated in the photodiode region 107, and increasing the effectiveness of a reset operation discharging the charge carriers in the floating diffusion region 111.

An annealing process may then be performed on the semiconductor substrate 101 to diffuse and/or activate various impurity ions implanted in the semiconductor substrate 101.

The CMOS image sensor and the method for manufacturing the same according to the embodiments as described above have the following effects.

The width of the transfer transistor may become large and/or the complementary impurity ions are implanted in the floating diffusion region so that the reset of the floating diffusion region is efficiently made and the electrons generated by light and transferred to the floating diffusion node have a relatively greater effect, making it possible to improve the characteristics of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A CMOS image sensor comprising:
a gate electrode on a gate insulating layer in an active region of a semiconductor substrate;
a photodiode region in the semiconductor substrate on one side of the gate electrode;
a floating diffusion region in the semiconductor substrate on another side of the gate electrode; and
a complementary impurity region in the semiconductor substrate on the other side of the gate electrode overlapping with the floating diffusion region.

2. The CMOS image sensor according to claim 1, wherein the gate electrode is in a transfer transistor.

3. The CMOS image sensor according to claim 1, wherein one side of the gate electrode is aligned with an end of the photodiode region.

4. The CMOS image sensor according to claim 1, wherein at least a portion of the complementary impurity region is adjacent to an isolation layer.

5. The CMOS image sensor according to claim 1, wherein at least a portion of the floating diffusion region is between the complementary impurity region and the gate electrode.

6. A method for manufacturing a CMOS image sensor comprising the steps of:
forming a gate electrode on a gate insulating layer in a predetermined region of a semiconductor substrate;
forming a photodiode region in the semiconductor substrate on one side of the gate electrode;
forming an insulating sidewall on sides of the gate electrode; and
forming a floating diffusion region in the semiconductor substrate on another side of the gate electrode; and
forming a complementary impurity region in the semiconductor substrate overlapping the floating diffusion region.

7. The method according to claim 6, wherein the gate electrode is in a transfer transistor.

8. The method according to claim 6, wherein one side of the gate electrode is aligned with an end of the photodiode region.

9. The method according to claim 6, wherein at least a portion of the complementary impurity region is adjacent to an isolation layer.

10. The method according to claim 6, wherein at least a portion of the floating diffusion region is between the complementary impurity region and the gate electrode.
